(19) United States
(12) Patent Application Publication
(10) Pub. No.: US 2026/0015223 A1
(43) Pub. Date: Jan. 15, 2026

(54) THREE-AXIS GYROSCOPE

(71) Applicant: AAC Kaitai Technologies (Wuhan) CO., LTD., Wuhan (CN)

(72) Inventors: Zhan Zhan, Shenzhen (CN); Zhao Ma, Shenzhen (CN); Xiao Kan, Shenzhen (CN); Shitao Yan, Shenzhen (CN); Shan Yang, Shenzhen (CN); Veronica Tan, Singapore (SG); Yang Li, Shenzhen (CN); Kahkeen Lai, Singapore (SG)

(21) Appl. No.: 19/337,815

(22) Filed: Sep. 23, 2025

Related U.S. Application Data
(63) Continuation-in-part of application No. 18/088,822, filed on Dec. 27, 2022.
Application No. 18/088,822 is a continuation of application No. PCT/CN2022/119632, filed on Sep. 19, 2022.

(30) Foreign Application Priority Data
Aug. 16, 2022 (CN) 202210981204.2

(51) Int. Cl. B81B 3/00; G01C 19/5712

(52) U.S. Cl. CPC B81B 3/0051; G01C 19/5712; B81B 2201/0242; B81B 2203/0145; B81B 2203/0307; B81B 2203/04; B81B 2203/056; B81B 2203/058

(57) ABSTRACT

The present invention provides a three-axis gyroscope and electronic products, including a drive structure used for driving the three-axis gyroscope, a first sensitive structure used for sensing an angular velocity in a first direction, a second sensitive structure used for sensing an angular velocity in the second direction, a third sensitive structure used for sensing an angular velocity in a third direction. The first sensitive structure, the second sensitive structure and the third sensitive structure can be mutually coupled in the first detection modality, the second detection modality and the third detection modality, which can effectively avoid the coupling error, achieve electrical orthogonal suppression and capacitance modality matching in the first detection modality, the second detection modality or the third detection modality, so that the structural performance loss can be compensated, thus reducing an orthogonal error and improving the detection accuracy and overall performance of the three-axis gyroscope.

### CROSS-REFERENCE TO RELATED APPLICATIONS

The application is a continuation in part of U.S. application Ser. No. 18/088,822, filed on 12, 27, 2022, which is a continuation of International Application No.PCT/CN2022/119632 filed on 09 19, 2022, the contents of which are incorporated herein by reference in their entireties.

### TECHNICAL FIELD

The present invention relates to the technical field of gyroscopes, in particular to a three-axis gyroscope.

### BACKGROUND

A micro-electromechanical system (MEMS) gyroscope in the prior art can detect an angular velocity according to the generation principle of Coriolis force. An angular velocity in any direction can be decomposed along the X axis, the Y axis and the Z axis in a space rectangular coordinate system. A three-axis gyroscope refers to a micromechanical gyroscope with the ability to measure angular velocities in of X, Y and Z axial directions. Therefore, the three-axis gyroscope can measure the direction and size of any angular velocity in a space. However, due to the mutual coupling in motion modalities in the X axis, the Y axis and the Z axis of the traditional three-axis gyroscope, an output of each detected axis will contain a large coupling error, and electrical orthogonal suppression and capacitance modality matching cannot be achieved at the same time. That is, the electrical control of a detection modality of a specific axis will affect the characteristics of the other axial detection modalities.

Therefore, it is necessary to provide a three-axis gyroscope to solve the above problems.

### SUMMARY

The present invention aims to provide a three-axis gyroscope to solve the following problems: the mutual coupling in the motion modalities in the X axis, the Y axis and the Z axis of a three-axis gyroscope electronic product in the prior art causes that an output of each detected axis will contain a large coupling error, and electrical orthogonal suppression and capacitance modality matching cannot be achieved at the same time. The technical scheme of the invention is as follows: the present invention provides a three-axis gyroscope, including a drive structure for driving the three-axis gyroscope, a first sensitive structure for sensing an angular velocity in a first direction; a second sensitive structure for sensing an angular velocity in a second direction; and a third sensitive structure for sensing an angular velocity in a third direction; wherein the three-axis gyroscope comprises first elastic members for connecting the first sensitive structure and the drive structure; the first sensitive structure comprises a first mass block and a second mass block, the first mass block and the second mass block are arranged along the second direction and are symmetrically arranged with respect to the first direction; the three-axis gyroscope further comprises second elastic members for connecting the second sensitive structure and the drive structure; the second sensitive structure comprises a third mass block and a fourth mass block, the third mass block and the fourth mass block are arranged along the second direction and are symmetrically arranged with respect to the first direction; the three-axis gyroscope further comprises third elastic members for connecting the third sensitive structure and the drive structure; the third sensitive structure comprises a fifth mass block and a sixth mass block, the fifth mass block and the sixth mass block are arranged along the second direction and are symmetrically arranged with respect to the first direction; and a plurality of anchoring structures for fixing the drive structure, the first sensitive structure, the second sensitive structure and the third sensitive structure; wherein the first direction, the second direction and the third direction are orthogonal to each other; the three-axis gyroscope has a drive modality, a first detection modality, a second detection modality and a third detection modality; the drive structure comprises first drive portions, drive arms, and third drive portions, and second drive portions are formed on the drive arms; the three-axis gyroscope comprises fourth elastic members, the first drive portions and the third drive portions are respectively connected to two end portions of the drive arms along the first direction through the fourth elastic members, and are respectively located on two sides of the second drive portions along the first direction; the first drive portions are connected with the first sensitive structure through the first elastic members; the second drive portions are connected with the second sensitive structure through the second elastic members; and the third drive portions are connected with the third sensitive structure through the third elastic members; each first drive portion comprises two ends disposed along the first direction; the plurality of anchoring structures including two first anchoring structures spaced apart along the first direction and disposed at the two ends of each first drive portion along the first direction, wherein each of the two first anchoring structures is correspondingly disposed at the respective end of the first drive portion along the first direction; and a first in-plane guide elastic member for connecting each first anchoring structure to the corresponding end of the first drive portion along the first direction; each third drive portion comprises two ends disposed along the first direction; the plurality of anchoring structures including two second anchoring structures spaced apart along the first direction and disposed at the two ends of each third drive portion along the first direction, wherein each of the two second anchoring structures is correspondingly disposed at the respective end of the third drive portion along the first direction; and a second in-plane guide elastic member for connecting each second anchoring structure to the corresponding end of the third drive portion along the first direction; the drive structure further comprises drive electrodes which are mounted on the first drive portions and the third drive portions; and the drive electrodes are spaced apart from the first drive portions and/or the third drive portions to form drive capacitance; the first drive portions and the third drive portions can move along the second direction, and drive the second drive portions to rotate through the fourth elastic members connected to the drive arms; in the drive modality, the first drive portions can drive the first mass block and the second mass block to move along the second direction and the first mass block and the second mass block can move towards or away from each other in the second direction; each of the third mass block and the fourth mass block is provided with a rotating shaft having an extending direction parallel to the third direction; the second drive portions drive the third mass block and the fourth mass block to rotate reversely around respective rotating shafts, and the third mass block and the fourth mass block have facing sides along the second direction, and the facing sides are simultaneously rotate towards the third sensitive structure or the first sensitive structure; the third drive portions can drive the fifth mass block and the sixth mass block to move along the second direction and the fifth mass block and the sixth mass block can move towards or away from each other in the second direction; wherein when the facing sides of the third mass block and the fourth mass block along the second direction rotate around the third direction toward the third sensitive structure, the fifth mass block and the sixth mass block move away from each other in the second direction, and the first mass block and the second mass block move towards each other in the second direction; motion directions of the first mass block and the fifth mass block are opposite; in the first detection modality, the drive structure, the second sensitive structure and the third sensitive structure remain stationary, the first mass block comprises a first end facing the second mass block in the second direction; the second mass block comprises a second end facing the first mass block in the second direction; the first end and the second end can move away from each other in the third direction, generating a vibration displacement in the third direction, and an angular velocity along the first direction can be acquired by detecting the vibration displacements of the first mass block and the second mass block in the third direction; in the second detection modality, the drive structure, the first sensitive structure and the third sensitive structure remain stationary, the third mass block and the fourth mass block rotate about the third direction in opposite directions to generate a vibration displacement in the third direction; and an angular velocity along the second direction can be acquired by detecting the vibration displacements of the third mass block and the fourth mass block in the third direction; in the third detection modality, the drive structure, the first sensitive structure and the second sensitive structure remain stationary, and the fifth mass block and the sixth mass block can move away from or towards each other in the first direction to generate a vibration displacement in the first direction, and an angular velocity along the second direction can be acquired by detecting the displacement along the first direction.

In one possible design, the first sensitive structure further comprises a first guide portion; the first guide portion comprises two ends disposed along the first direction; the plurality of anchoring structures including two third anchoring structures spaced apart along the first direction and disposed at the two ends the first guide portion along the first direction, wherein each of the two third anchoring structures is correspondingly disposed at the respective end of the first guide portion along the first direction; and the three-axis gyroscope further comprises fifth elastic members for connecting each third anchoring structure to the corresponding end of the first guide portion along the first direction; the first guide portion further comprises two ends disposed along the second direction, the three-axis gyroscope further comprises sixth elastic members for connecting one end of the first guide portion along the second direction to the first mass block and the other end of the first guide portion along the second direction to the second mass block along the second direction; in the drive modality, the first guide portion is pulled by the first mass block and the second mass block to remain stationary, so as to prevent the first mass block and the second mass block from moving in the same direction along the second direction; and in the first detection modality, the first guide portion is pulled by the first mass block and the second mass block to rotate around the third direction with the third direction as the rotation axis.

In one possible design, the second sensitive structure further comprises a second guide portion; the second guide portion comprises two ends disposed along the first direction; the plurality of anchoring structures including two fourth anchoring structures spaced apart along the first direction and disposed at the two ends of the second guide portion along the first direction, wherein each of the two fourth anchoring structures is correspondingly disposed at the respective end of the second guide portion along the first direction; and the three-axis gyroscope further comprises seventh elastic members for connecting each fourth anchoring structure to the corresponding end of the second guide portion along the first direction; the second guide portion further comprises two ends disposed along the second direction, the three-axis gyroscope further comprises eighth elastic members for connecting one end of the second guide portion along the second direction to the third mass block and the other end of the second guide portion along the second direction to the fourth mass block along the second direction; in the drive modality, the second guide portion is pulled by the third mass block and the fourth mass block to do reciprocating motion along the first direction, so as to prevent the third mass block and the fourth mass block from rotating in the same direction along the third direction; and in the second detection modality, the second guide portion is pulled by the third mass block and the fourth mass block and capable of doing reciprocating motion along the third direction.

In one possible design, the third sensitive structure further comprises a third guide portion; the third guide portion comprises two first guide blocks extending along the second direction arranged symmetrically in the second direction, and two second guide blocks extending along the first direction arranged symmetrically in the first direction; each of the first guide blocks comprises two ends disposed along the second direction; the plurality of anchoring structures including two fifth anchoring structures spaced apart along the second direction and disposed at the two ends of each first guide block along the second direction, wherein each of the two fifth anchoring structures is correspondingly disposed at the respective end of the first guide block along the second direction; and a third in-plane guide elastic member for connecting each fifth anchoring structure to the corresponding end of the first guide block along the second direction; each of the second guide blocks comprises two ends disposed along the first direction; the plurality of anchoring structures including two sixth anchoring structures spaced apart along the first direction and disposed at the two ends of each second guide block along the first direction, wherein each of the two sixth anchoring structures is correspondingly disposed at the respective end of the second guide block along the first direction; and a fourth in-plane guide elastic member for connecting each sixth anchoring structure to the corresponding end of the second guide block along the first direction; the three-axis gyroscope further comprises ninth elastic members, each first guide block has a first side surface facing the other first guide block along the first direction, and the first side surface is connected to the two second guide blocks via the ninth elastic members; the three-axis gyroscope further comprises tenth elastic members, each second guide block has a second side surface facing the second direction away from the other second guide block, the tenth elastic members for connecting the second side surface of one second guide block to the fifth mass block and the second side surface of the other second guide block to the sixth mass block; in the drive modality, the second guide blocks are pulled by the fifth mass block and the sixth mass block to reversely move along the second direction, and the first guide blocks are pulled by the second guide blocks to reversely move along the first direction, thereby preventing the fifth mass block and the sixth mass block from moving in the same direction.

In one possible design, the third sensitive structure further comprises a first detection block and a second detection block which are symmetrically arranged along the first direction; the first detection block comprises two ends disposed along the second direction; the plurality of anchoring structures including two seventh anchoring structures spaced apart along the second direction and disposed at the two ends of first detection block along the second direction, wherein each of the two seventh anchoring structures is correspondingly disposed at the respective end of the first detection block along the second direction; and a fifth in-plane guide elastic member for connecting each seventh anchoring structure to the corresponding end of the first detection block along the second direction; the first detection block comprises two ends disposed along the first direction; the three-axis gyroscope further comprises eleventh elastic members for connecting the two ends of the first detection block along the first direction and the fifth mass block; the second detection block comprises two ends disposed along the second direction; the plurality of anchoring structures including two eighth anchoring structures spaced apart along the second direction and disposed at the two ends of second detection block along the second direction, wherein each of the two eighth anchoring structures is correspondingly disposed at the respective end of the second detection block along the second direction; and a sixth in-plane guide elastic member for connecting each eighth anchoring structure to the corresponding end of the second detection block along the second direction; the second detection block comprises two ends disposed along the first direction; the three-axis gyroscope further comprises twelfth elastic members for connecting the two ends of the second detection block along the first direction and the sixth mass block; in the drive modality, the first detection block and the second detection block remain stationary; in the third detection modality, the first detection block and the fifth mass block have the same direction of motion; and the second detection block and the sixth mass block have the same direction of motion.

In one possible design, the third sensitive structure further comprises two third detection blocks symmetrically arranged along the second direction, two fourth detection blocks symmetrically arranged along the second direction and two coupling levers symmetrically arranged along the second direction, and both the third detection blocks and the fourth detection blocks extend along the second direction, the third detection blocks and the fourth detection blocks are symmetrically arranged about the first direction; the three-axis gyroscope further comprises thirteenth elastic members, along the first direction, one end of each of the two third detection blocks is connected with the fifth mass block through one of the thirteenth elastic members, and the other end is connected with one of the two coupling levers through one of the thirteenth elastic members; one end of each of the two fourth detection blocks is connected with the sixth mass block through one of the thirteenth elastic members, and the other end is connected with one of the two coupling levers through one of the thirteenth elastic members; along the second direction, each of the third detection blocks comprises two ends disposed along the second direction; the plurality of anchoring structures including two ninth anchoring structures spaced apart along the second direction and disposed at the two ends of third detection block along the second direction, wherein each of the two ninth anchoring structures is correspondingly disposed at the respective end of the third detection block along the second direction; and a seventh in-plane guide elastic member for connecting each ninth anchoring structure to the corresponding end of the third detection block along the second direction; each of the fourth detection blocks comprises two ends disposed along the second direction; the plurality of anchoring structures including two tenth anchoring structures spaced apart along the second direction and disposed at the two ends of fourth detection block along the second direction, wherein each of the two tenth anchoring structures is correspondingly disposed at the respective end of the fourth detection block along the second direction; and an eighth in-plane guide elastic member for connecting each tenth anchoring structure to the corresponding end of the fourth detection block along the second direction; in the drive modality, the third detection blocks and the fourth detection blocks remain stationary; in the third detection modality, the two third detection blocks move in the same direction with the fifth mass block; the two fourth detection blocks move in the same direction with the sixth mass block; and the coupling levers are pulled by the third detection blocks and the fourth detection blocks to rotate around the third direction, and the rotation direction of the coupling levers is the same.

In one possible design, the three-axis gyroscope further comprises first transducers, second transducers, and third transducers; along the third direction, the first transducers and the first sensitive structure are spaced apart to form capacitance, a change in the distance between the first transducers and the first sensitive structure causes the capacitance to change, and the capacitance change for detecting the vibration displacement of the first sensitive structure along the third direction, or preventing an orthogonal error of the first detection modality, or matching the frequencies of the drive modality and the first detection modality; along the third direction, the second transducers and the second sensitive structure are spaced apart to form capacitance, a change in the distance between the second transducers and the second sensitive structure causes the capacitance to change, and the capacitance change for detecting the vibration displacement of the second sensitive structure along the third direction, or preventing an orthogonal error of the second detection modality, or matching the frequencies of the drive modality and the second detection modality; and the third transducers and the third sensitive structure are located in the same plane perpendicular to the third direction, and the third transducers and the third sensitive structure are spaced apart to form capacitance, a change in the distance between the third transducers and the third sensitive structure causes the capacitance to change, and the capacitance change for detecting the vibration displacement of the third sensitive structure along the first direction, or preventing an orthogonal error of the third detection modality, or matching the frequencies of the drive modality and the third detection modality.

In one possible design, the second sensitive structure further comprises rotational guide elastic members; the third mass block and the fourth mass block are provided with first hole structures; and the rotational guide elastic members are located in the first hole structures.

In one possible design, the fifth mass block is provided with a first sunken portion and the sixth mass block is provided with a second sunken portion; the first detection block is disposed within the first sunken portion of the fifth mass block and is connected to the fifth mass block; the second detection block is disposed within the second sunken portion of the sixth mass block and is connected to the sixth mass block.

In one possible design, two drive structures spaced along the second direction, one drive structure positioned on a side of the second mass block facing away from the third mass block, and the other drive structure positioned on a side of the third mass block facing away from the second mass block; each drive structure consists of a drive arm extending along the first direction, having a first drive portion connected at one end along the first direction and a third drive portion connected at the other end along the first direction, and a second drive portion extending from the middle of the drive arm along the second direction toward the other drive structure, the drive structure being connected to the second sensitive structure exclusively through the second drive portion.

The beneficial effects of the present invention lie in: the three-axis gyroscope of the present invention has a simple structure and high detection sensitivity. The first sensitive structure, the second sensitive structure and the third sensitive structure are independent of each other, and can be mutually coupled in the first detection modality, the second detection modality and the third detection modality, without interference, so that a large coupling error generated by the coupling of the first sensitive structure, the second sensitive structure and the third sensitive structure during detection of the angular velocities in different directions can be effectively avoided, and the detection accuracy of the three-axis gyroscope is improved. On the other hand, the three-axis gyroscope of this structure can simultaneously achieve electrical orthogonal suppression and capacitance modality matching in the first detection modality, the second detection modality or the third detection modality, so that the structural performance loss caused by asymmetry of machining can be compensated, thus reducing an orthogonal error and improving the detection accuracy and overall performance of the three-axis gyroscope.

It should be understood that the general description above and the detailed description below are only illustrative and do not limit this application.

### BRIEF DESCRIPTION OF THE DRAWINGS

FIG. 1 is a schematic structural diagram of a three-axis gyroscope provided according to the present invention in one embodiment;

FIG. 2 is a schematic structural diagram of the three-axis gyroscope in FIG. 1 in a drive modality;

FIG. 3 is a schematic structural diagram of the three-axis gyroscope in FIG. 1 in a first detection modality;

FIG. 4 is a sectional view of a first sensitive structure in FIG. 3 along direction A-A;

FIG. 5 is a schematic structural diagram of the three-axis gyroscope in FIG. 1 in a second detection modality;

FIG. 6 is a sectional view of a second sensitive structure in FIG. 5 along direction B-B;

FIG. 7 is a schematic structural diagram of the three-axis gyroscope in FIG. 1 in a third detection modality;

FIG. 8 is a schematic structural diagram of a three-axis gyroscope provided according to the present invention in another embodiment;

FIG. 9 is a schematic structural diagram of the three-axis gyroscope in FIG. 8 in a drive modality;

FIG. 10 is a schematic structural diagram of the three-axis gyroscope provided in FIG. 8 in a first detection modality;

FIG. 11 is a sectional view of a first sensitive structure in FIG. 10 along direction C-C;

FIG. 12 is a schematic structural diagram of the three-axis gyroscope in FIG. 8 in a second detection modality;

FIG. 13 is a sectional view of a second sensitive structure in FIG. 12 along direction D-D;

FIG. 14 is a schematic structural diagram of the three-axis gyroscope in FIG. 8 in a third detection modality;

FIG. 15 is a schematic structural diagram of a three-axis gyroscope provided according to the present invention in yet another embodiment;

FIG. 16 is a schematic structural diagram of the three-axis gyroscope in FIG. 15 in a drive modality; and

FIG. 17 is a schematic structural diagram of the three-axis gyroscope in FIG. 15 in a third detection modality.

The accompanying drawings, which are incorporated herein by reference and form a part of this specification, illustrate embodiments consistent with the present application and, together with the description, serve to explain the principles of the present application.

### DETAILED DESCRIPTION OF THE EMBODIMENTS

The present invention is further described below in combination with accompanying drawings and implementations.

The terms used in the embodiments of the present invention are only for the purpose of describing the specific embodiments, and are not intended to limit the present invention. The singular forms of “a”, “said”, and “the” used in the embodiments of the present invention and the claims are also intended to include plural forms, unless the context clearly indicates other meanings.

It should be understood that the term “and/or” herein is only an association relationship that describes associated objects, and represents that there can be three relationships. For example, A and/or B can represent that: A exists alone, A and B exist simultaneously, and B exists alone. In addition, the character “/” herein generally indicates that the front and back associated objects are in an “or” relationship.

It should be noted that the directional terms such as “above”, “below”, “left”, and “right” described in the embodiments of the present invention are described from the angles shown in the drawings, and should not be construed as limiting the embodiments of the present invention. In addition, in this context, it should also be understood that when an element is referred to as being “above” or “below” another element, it can not only be directly connected “above” or “below” another element, but also indirectly connected to the “above” or “below” of another element through an intermediate.

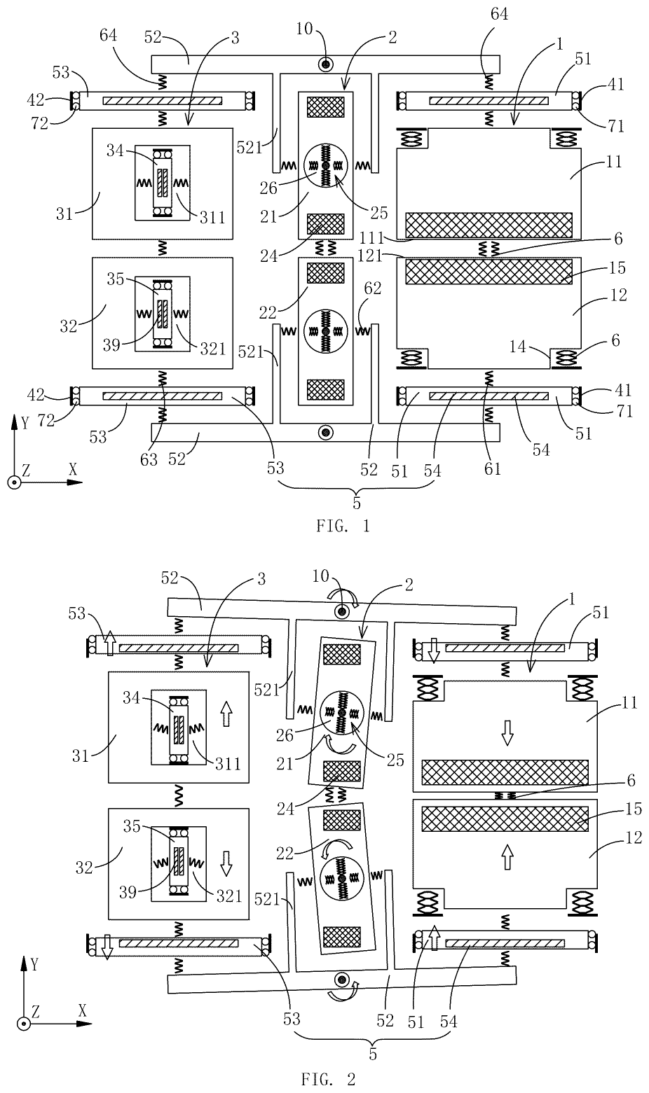

The present invention provides a three-axis gyroscope, as shown in FIG. 1 to FIG. 7, including a drive structure 5 for driving the three-axis gyroscope, a first sensitive structure 1 for sensing an angular velocity in a first direction X, a second sensitive structure 2 for sensing an angular velocity in a second direction Y, a third sensitive structure 3 for sensing an angular velocity in a third direction Z, and a plurality of anchoring structures for fixing the drive structure 5, the first sensitive structure 1, the second sensitive structure 2 and the third sensitive structure 3.

The drive structure 5 for driving the three-axis gyroscope. The first sensitive structure 1 for sensing an angular velocity in a first direction X. The three-axis gyroscope comprises first elastic members 61 for connecting the first sensitive structure 1 and the drive structure 5. The first sensitive structure 1 includes a first mass block 11 and a second mass block 12, the first mass block 11 and the second mass block 12 are arranged along the second direction Y and are symmetrically arranged with respect to the first direction X. The three-axis gyroscope further comprises second elastic members 62 for connecting the second sensitive structure 1 and the drive structure 5. The second sensitive structure 2 includes a third mass block 21 and a fourth mass block 22, the third mass block 21 and the fourth mass block 22 are arranged along the second direction Y and are symmetrically arranged with respect to the first direction X. The three-axis gyroscope further comprises third elastic members 63 for connecting the third sensitive structure 3 and the drive structure 5. The third sensitive structure 3 includes a fifth mass block 31 and a sixth mass block 32, the fifth mass block 31 and the sixth mass block 32 are arranged along the second direction Y and are symmetrically arranged with respect to the first direction X;

The first direction X, the second direction Y and the third direction Z are orthogonal to each other. The three-axis gyroscope has a drive modality, a first detection modality, a second detection modality and a third detection modality.

In the drive modality as shown in FIGS. 1-2, the drive structure 5 can drive the first mass block 11 and the second mass block 12 of the first sensitive structure 1 to move reversely in a reciprocating manner along the second direction Y through the first elastic members 61, causing differential linear motion between the first mass block 11 and the second mass block 12. Each of the third mass block 21 and the fourth mass block 22 is provided with a rotating shaft with an extending direction parallel to the third direction Z. The drive structure 5 can also drive the third mass block 21 and the fourth mass block 22 of the second sensitive structure 2 to rotate reversely around their own rotating shafts, and the third mass block 21 and the fourth mass block 22 have facing sides along the second direction Y, and the facing sides are simultaneously rotate towards the third sensitive structure 3 or the first sensitive structure; causing differential rotation motion between the third mass block 21 and the fourth mass block 22. Meanwhile, the drive structure 5 can also drive the fifth mass block 31 and the sixth mass block 32 of the third sensitive structure 3 to move reversely in a reciprocating manner along the second direction Y through the third elastic members 63, causing differential linear motion between the fifth mass block 31 and the sixth mass block 32. When the facing sides of the third mass block 21 and the fourth mass block 22 along the second direction Y rotate around the third direction Z toward the third sensitive structure 3, the fifth mass block and the sixth mass block move away from each other in the second direction, and the first mass block and the second mass block are move towards each other in the second direction. Motion directions of the first mass block 11 and the fifth mass block 31 are opposite.

When the three-axis gyroscope receives an externally applied angular velocity along the first direction X, the second direction Y or the third direction Z, the first sensitive structure 1, the second sensitive structure 2 or the third sensitive structure 3 generates a Coriolis force due to the angular velocity according to the Coriolis principle, and the Coriolis force will force the first sensitive structure 1, the second sensitive structure 2 or the third sensitive structure 3 of the three-axis gyroscope to generate a vibration perpendicular to its motion direction in the drive modality to make the three-axis gyroscope in the first detection modality, the second detection modality or the third detection modality. By means of detecting the vibration displacement of the first sensitive structure 1, the second sensitive structure 2 or the third sensitive structure 3, and transmitting the detected structure to a computing system (not shown in the figure), the computing system calculates the angular velocity applied to the three-axis gyroscope according to the received data.

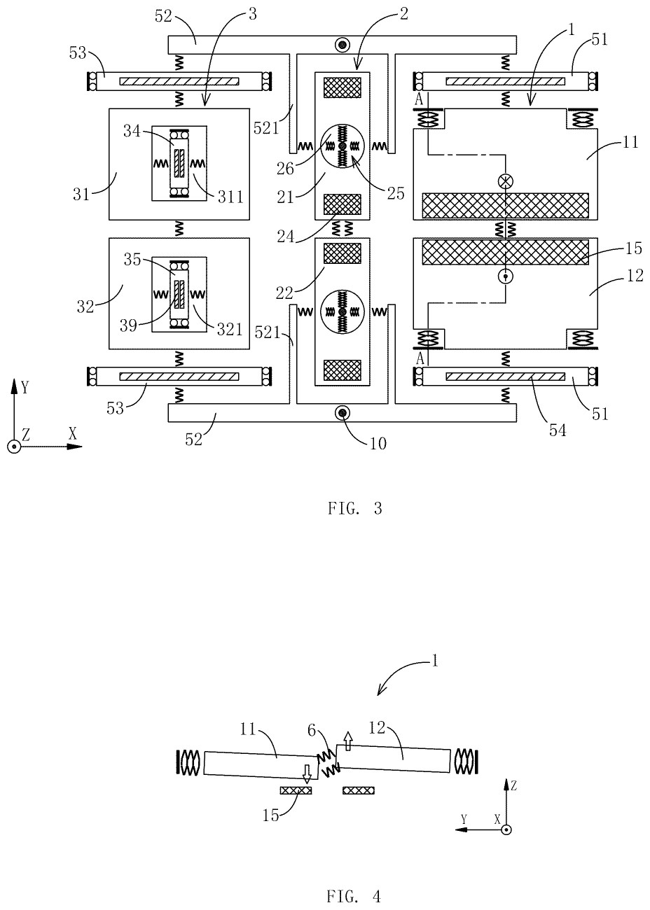

Specifically, when the three-axis gyroscope is subjected to the angular velocity along the first direction X, the three-axis gyroscope is in the first detection modality as shown in FIG. 3 and FIG. 4. In the first detection modality, the drive structure 5, the second sensitive structure 2 and the third sensitive structure 3 can remain stationary. The first sensitive structure 1 generates a Coriolis force along the third direction Z due to the impact of the angular velocity along the first direction X. The direction of the Coriolis force at certain time is shown in the arrow directions in FIG. 3 and FIG. 4. The first mass block 11 comprises a first end 111 facing the second mass block 12 in the second direction Y; the second mass block 12 comprises a second end 121 facing the first mass block 11 in the second direction Y; the first end 111 and the second end 121 can move away from each other in the third direction Z. The Coriolis force will force the opposite sides of the first mass block 11 and the second mass block 12 to reversely flip towards the third direction Z, causing differential rotation motion between the first mass block 11 and the second mass block 12, thus generating the vibration displacement in the third direction Z. The angular velocity along the first direction X can be acquired by means of detecting the vibration displacements of the first mass block 11 and the second mass block in the third direction.

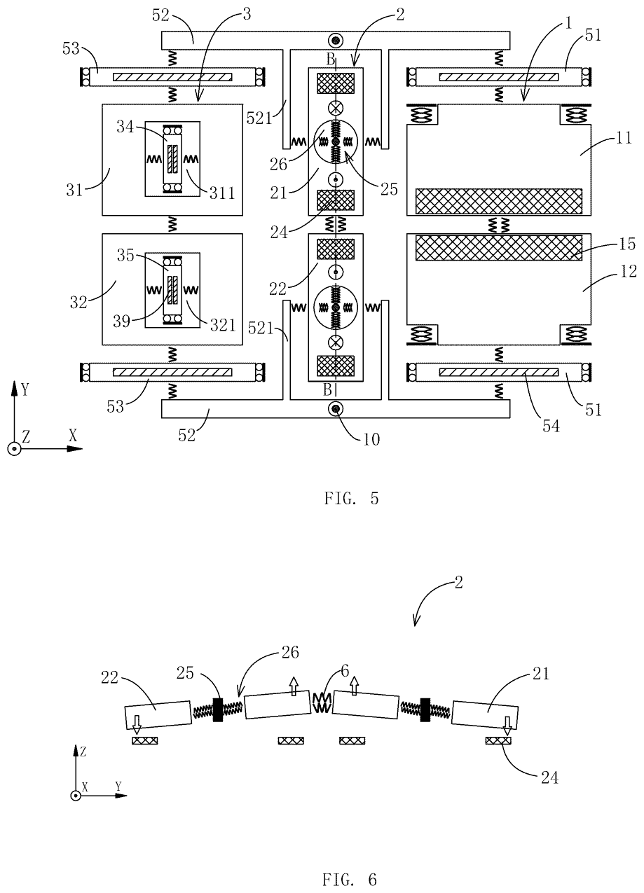

When the three-axis gyroscope is subjected to the angular velocity along the second direction Y, the three-axis gyroscope is in the second detection modality as shown in FIG. 5 and FIG. 6. In the second detection modality, the drive structure 5, the first sensitive structure 1 and the third sensitive structure 3 can remain stationary. The second sensitive structure 2 generates a Coriolis force along the third direction Z due to the impact of the angular velocity along the second direction Y. The direction of the Coriolis force at certain time is shown in the arrow directions in FIG. 5 and FIG. 6. The Coriolis force will force the third mass block 21 and the fourth mass block 22 to reversely flip around their own rotating shafts along the third direction Z, that is the third mass block 21 and the fourth mass block 22 rotate about their respective rotating shafts in the third direction Z, and the rotational directions of the third mass block 21 and the fourth mass block 22 are opposite to each other causing differential rotation motion between the third mass block 21 and the fourth mass block 22, thus generating the vibration displacement in the third direction Z. The angular velocity along the second direction Y can be acquired by means of detecting the vibration displacements of the third mass block 21 and the fourth mass block 22 along the third direction.

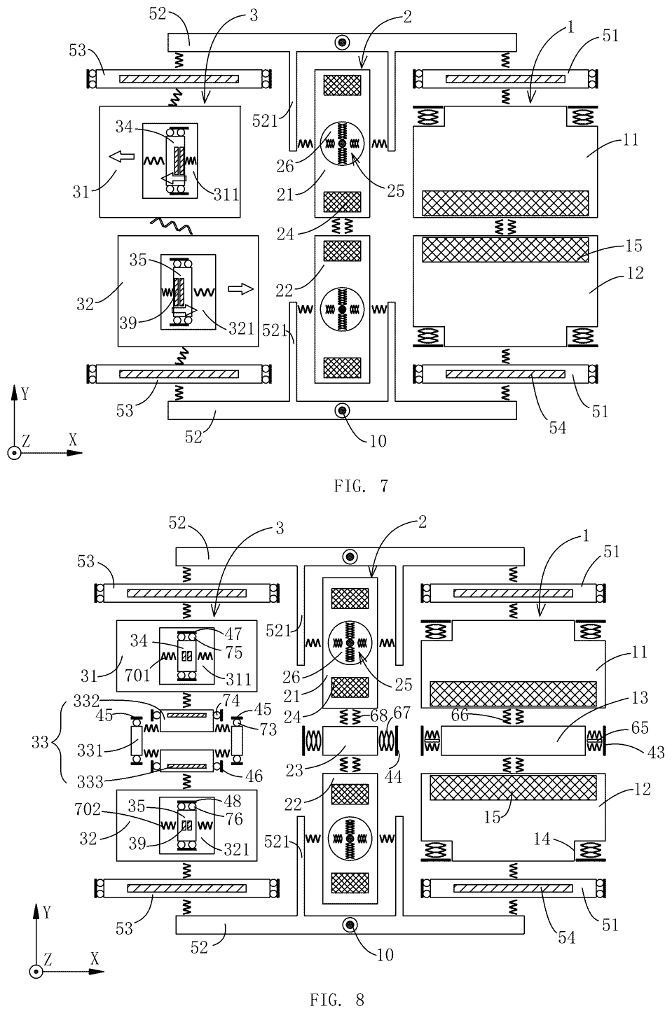

When the three-axis gyroscope is subjected to the angular velocity along the third direction Z, the three-axis gyroscope is in the third detection modality as shown in FIG. 7. In the third detection modality, the drive structure 5, the first sensitive structure 1 and the third sensitive structure 2 can remain stationary. The third sensitive structure 3 generates a Coriolis force along the first direction X due to the impact of the angular velocity along the third direction Z. The direction of the Coriolis force at certain time is shown in the arrow direction FIG. 7. The Coriolis force will force the fifth mass block 31 and the sixth mass block 32 to reversely move in a reciprocating manner along the first direction X, causing differential linear motion between the fifth mass block 31 and the sixth mass block 32, thus generating the vibration displacement in the first direction X. The angular velocity along the second direction Y can be acquired by means of detecting the displacement along the first direction X.

Therefore, the three-axis gyroscope of the present invention has a simple structure and high detection sensitivity. The first sensitive structure 1, the second sensitive structure 2 and the third sensitive structure 3 are independent of each other, and can be mutually coupled in the first detection modality, the second detection modality and the third detection modality, without interference, so that a large coupling error generated by the coupling of the first sensitive structure 1, the second sensitive structure 2 and the third sensitive structure 3 during detection of the angular velocities in different directions can be effectively avoided, and the detection accuracy of the three-axis gyroscope is improved. On the other hand, the three-axis gyroscope of this structure can simultaneously achieve electrical orthogonal suppression and capacitance modality matching in the first detection modality, the second detection modality or the third detection modality, so that the structural performance loss caused by asymmetry of machining can be compensated, thus reducing an orthogonal error and improving the detection accuracy and overall performance of the three-axis gyroscope.

In addition, the gyroscope of the present invention is symmetrically arranged in the second direction Y, and the first sensitive structure 1, the second sensitive structure 2 and the third sensitive structure 3 in the drive modality, the first detection modality, the second detection modality and the third detection modality are all in differential motions, which can effectively improve the stability of the motion of the three-axis gyroscope and facilitate differential detection, and can effectively prevent the influence of common mode interferences such as acceleration and impact to further improve the overall performance of the three-axis gyroscope.

The first mass block 11 and the second mass block 12, the third mass block 21 and the fourth mass block 22, the fifth mass block 31 and the sixth mass block 32 are all respectively connected through elastic members 6. In one specific embodiment, as shown in FIG. 2 to FIG. 4, the first mass block 11 and the second mass block 12 are connected through an elastic member 6, so that the first mass block 11 and the second mass block 12 can be coupled with each other. In the drive modality as shown in FIG. 2, the elastic member 6 between the first mass block 11 and the second mass block 12 can drive the first mass block 11 and the second mass block 12 to move along the second direction Y with the drive structure 5, thus deforming along the second direction Y, and the reciprocating differential linear motion can be formed between the first mass block 11 and the second mass block 12. In the first detection modality as shown in FIG. 3 and FIG. 4, the elastic member 6 can deform when the first mass block 11 and the second mass block 12 reversely flip under the action of the Coriolis force, so that the first mass block 11 and the second mass block 12 can pull each other to do differential rotation motion in a plane perpendicular to the first direction X, which is convenient for realizing differential detection and improves the motion stability of the first mass block 11 and the second mass block 12.

In another specific embodiment, as shown in FIG. 8 to FIG. 11, the first sensitive structure 1 can also include a first guide portion 13. the first guide portion 13 comprises two ends disposed along the first direction X; the plurality of anchoring structures including two third anchoring structures 43 spaced apart along the first direction X and disposed at the two ends the first guide portion 13 along the first direction X, wherein each of the two third anchoring structures 43 is correspondingly disposed at the respective end of the first guide portion 13 along the first direction X; and the three-axis gyroscope further comprises fifth elastic members 65 for connecting each third anchoring structure 43 to the corresponding end of the first guide portion 13 along the first direction X; the first guide portion 13 further comprises two ends disposed along the second direction Y, the three-axis gyroscope further comprises sixth elastic members 66 for connecting one end of the first guide portion 13 along the second direction Y to the first mass block 11 and the other end of the first guide portion 13 along the second direction Y to the second mass block 12 along the second direction Y.

In the drive modality, the first guide portion 13 is easily pulled by the first mass block 11 and the second mass block 12 to remain stationary, so as to prevent the first mass block 11 and the second mass block 12 from moving in the same direction along the second direction Y.

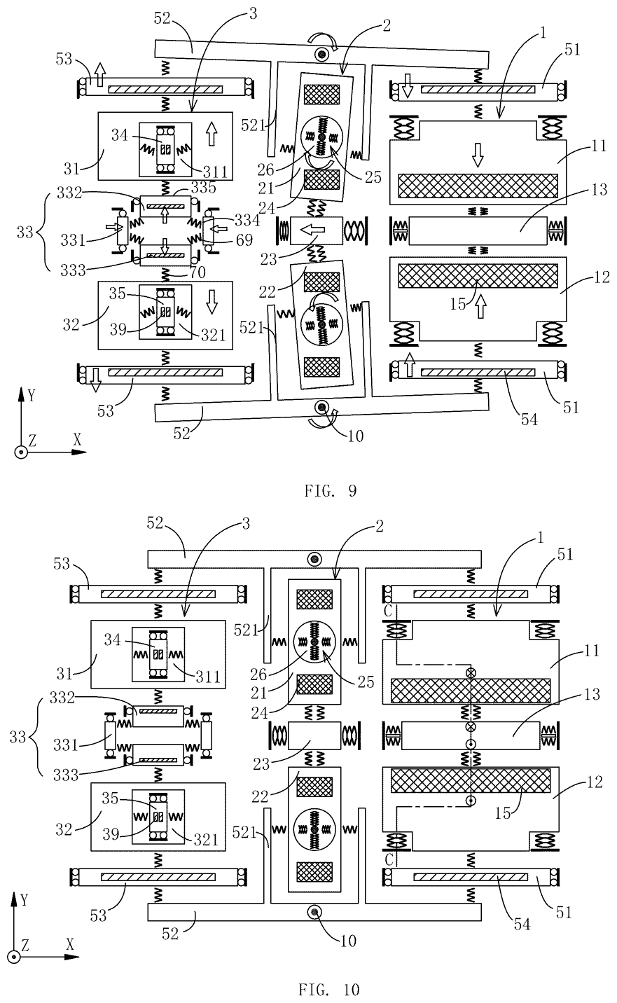

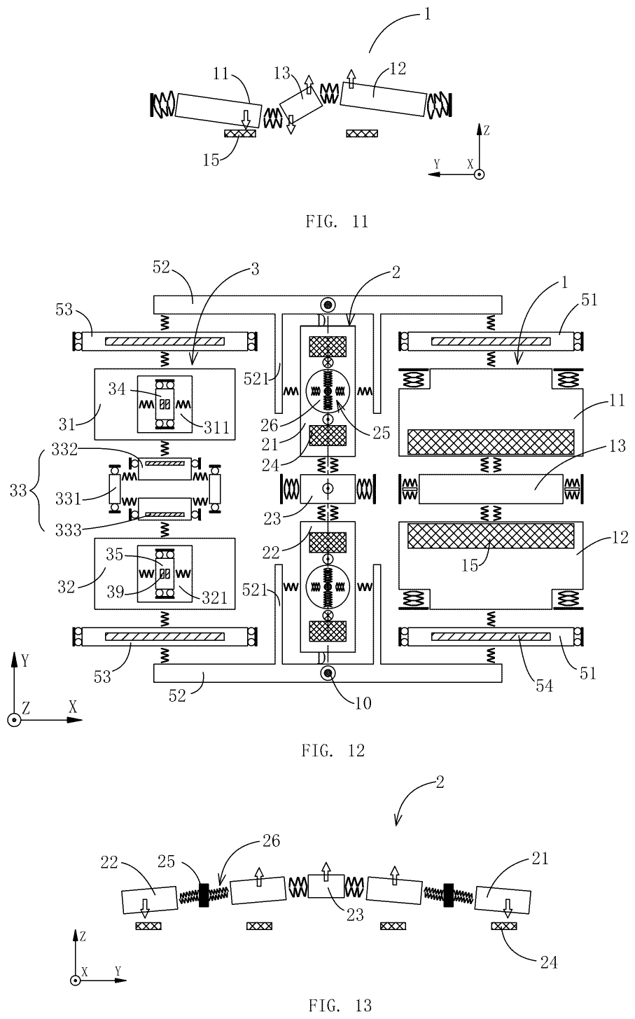

In the first detection modality as shown in FIG. 10 and FIG. 11, the first guide portion 13 can be pulled by the first mass block 11 and the second mass block 12 to rotate towards the third direction Z. The force directions of the first guide portion 13 at certain time are represented by the arrow directions in FIG. 9, FIG. 10 and FIG. 11.

In this embodiment, the fifth elastic members 65 and the sixth elastic members 66 are structure that can rotate around the first direction X, and are hard to deform in the first direction X, the second direction Y or the third direction Z. Two ends of the first guide portion 13 along the first direction X are connected to the third anchoring structures 43 through the fifth elastic members 65, so that the first guide portion 13 can rotate in a plane perpendicular to the first direction X, and can be prevented from moving in the second direction Y.

In the drive modality as shown in FIG. 9, the two ends of the first guide portion 13 along the second direction Y will not move with the motion of the first mass block 11 or the second mass block 12, so that the first mass block 11 and the second mass block 12 can simultaneously do the differential linear motion towards or away from the first guide portion 13 under the drive of the drive structure 5, thus reducing the motion interference between the first mass block 11 and the second mass block 12, and avoiding the first mass block 11 and the second mass block 12 from moving in the same direction in the drive modality due to the mutual interference or the interference of the drive structure 5 to make the three-axis gyroscope in a parasitic modality. In the first detection modality as shown in FIG. 10 and FIG. 11, the first guide portion 13 can increase a displacement difference in the third direction Z between the first mass block 11 and the second mass block 12, which is more convenient for differential detection and improves the detection accuracy of the three-axis gyroscope.

Therefore, the arrangement of the first guide portion 13 can prevent the first mass block 11 and the second mass block 12 from moving in the same direction along the second direction Y, increase a frequency difference between the drive modality and the parasitic modality, reduce linear impact, vibration interference and other interferences in the same direction output by the first sensitive structure 1, and effectively improve the quality factor of the three-axis gyroscope in the drive modality.

In one specific embodiment, as shown in FIG. 2, FIG. 5 and FIG. 6, the third mass block 21 and the fourth mass block 22 are connected through an elastic member 6, so that the third mass block 21 and the fourth mass block 22 can be coupled with each other. In the drive modality as shown in FIG. 2, the elastic member 6 between the third mass block 21 and the fourth mass block 22 can deform with the rotation of the third mass block 21 and the fourth mass block 22, so that the differential rotation motion in the plane perpendicular to the first direction X can be formed between the third mass block 21 and the fourth mass block 22. In the second detection modality as shown in FIG. 5 and FIG. 6, the elastic member 6 can deform when the third mass block 21 and the fourth mass block 22 reversely flip under the action of the Coriolis force, so that the third mass block 21 and the fourth mass block 22 can pull each other to do differential rotation motion in the plane perpendicular to the first direction X, which is convenient for realizing differential detection and improves the motion stability of the third mass block 21 and the fourth mass block 22.

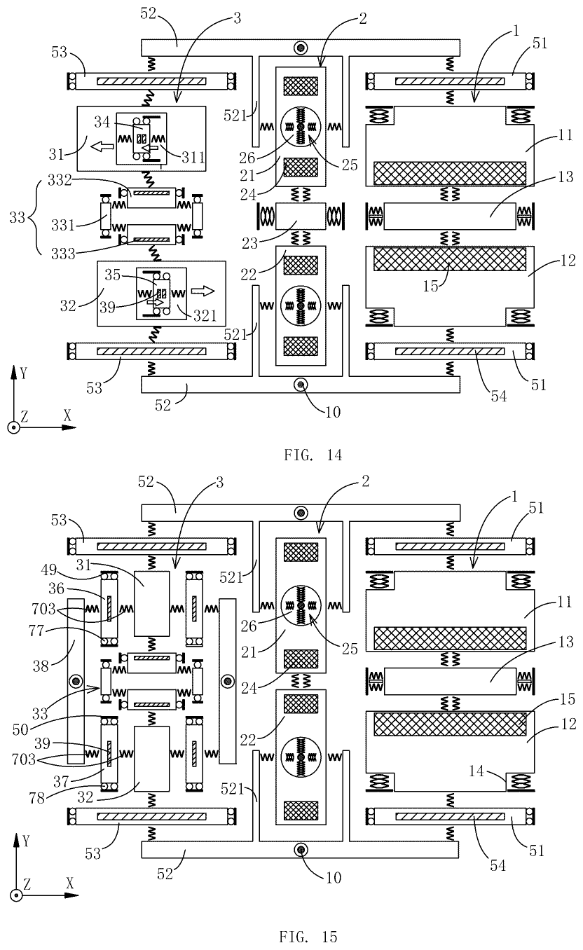

In another specific embodiment, as shown in FIG. 9, FIG. 12 and FIG. 13, the second sensitive structure 2 can also include a second guide portion 23. The second guide portion 23 comprises two ends disposed along the first direction X; the plurality of anchoring structures including two fourth anchoring structures 44 spaced apart along the first direction X and disposed at the two ends of the second guide portion 23 along the first direction, wherein each of the two fourth anchoring structures 44 is correspondingly disposed at the respective end of the second guide portion 23 along the first direction X; and the three-axis gyroscope further comprises seventh elastic members 67 for connecting each fourth anchoring structure 44 to the corresponding end of the second guide portion 23 along the first direction X; the second guide portion 23 further comprises two ends disposed along the second direction Y, the three-axis gyroscope further comprises eighth elastic members 68 for connecting one end of the second guide portion 23 along the second direction Y to the third mass block 21 and the other end of the second guide portion 23 along the second direction Y to the fourth mass block 22 along the second direction Y.

In the drive modality, the second guide portion 23 is easily pulled by the third mass block 21 and the fourth mass block 22 to do reciprocating motion along the first direction X, so as to prevent the third mass block 21 and the fourth mass block 22 from rotating in the same direction along the third direction Z.

In the second detection modality, the second guide portion 23 can be pulled by the third mass block 21 and the fourth mass block 22 to do reciprocating motion along the third direction Z. The force directions of the second guide portion 23 at certain time are represented by the arrow directions in FIG. 9, FIG. 12 and FIG. 13.

In this embodiment, the seventh elastic members 67 and the eighth elastic members 68 are structures that can deform along the first direction X and can also rotate towards the third direction Z.

In the drive modality as shown in FIG. 9, two ends of the second guide portion 23 along the second direction Y can be pulled by the third mass block 21 and the fourth mass block 22 to generate reciprocating motion along the first direction X, while the second guide portion 23 can also guide the third mass block 21 and the fourth mass block 22 to rotate towards the same side, so that the rotation directions of the third mass block 21 and the fourth mass block 22 are different (for example, the third mass block 21 rotates clockwise, and the fourth mass block 22 rotates anticlockwise) to form the differential rotation motion, thus avoiding the third mass block 21 and the fourth mass block 22 from rotating in the same direction in the drive modality due to the interference of the drive structure 5 to make the three-axis gyroscope in the parasitic modality. Furthermore, in the second detection modality as shown in FIG. 12 and FIG. 13, the second guide portion 23 can increase a displacement difference in the third direction Z between the third mass block 21 and the fourth mass block 22, which is more convenient for differential detection and improves the detection accuracy of the three-axis gyroscope.

Therefore, the arrangement of the second guide portion 23 can prevent the third mass block 21 and the fourth mass block 22 from rotating in the same direction in the plane perpendicular to the third direction Z, increase a frequency difference between the drive modality and the parasitic modality, reduce linear impact, vibration interference and other interferences in the same direction output by the second sensitive structure 2, and effectively improve the quality factor of the three-axis gyroscope in the drive modality.

In one specific embodiment, as shown in FIG. 2 and FIG. 7, the fifth mass block 31 and the sixth mass block 32 are connected through an elastic member 6, so that the fifth mass block 31 and the sixth mass block 32 can be coupled with each other. In the drive modality as shown in FIG. 2, the elastic member 6 between the fifth mass block 31 and the sixth mass block 32 can drive the fifth mass block 31 and the sixth mass block 32 to move along the second direction Y with the drive structure 5, thus deforming along the second direction Y, and the reciprocating differential linear motion can be formed between the fifth mass block 31 and the sixth mass block 32. In the third detection modality as shown in FIG. 7, the elastic member 6 can deform when the fifth mass block 31 and the sixth mass block 32 move along the first direction X under the action of the Coriolis force, so that the fifth mass block 31 and the sixth mass block 32 can pull each other to do differential linear motion in the first direction X, which is convenient for realizing differential detection and improves the motion stability of the fifth mass block 31 and the sixth mass block 32.

In another specific embodiment, as shown in FIG. 9 and FIG. 14, the third sensitive structure 3 can also include a third guide portion 33. The third guide portion 33 comprises two first guide blocks 331 extending along the second direction Y arranged symmetrically in the second direction Y, and two second guide blocks 332 extending along the first direction X arranged symmetrically in the first direction X. each of the first guide blocks 331 comprises two ends disposed along the second direction Y; the plurality of anchoring structures including two fifth anchoring structures 45 spaced apart along the second direction Y and disposed at the two ends of each first guide block 331 along the second direction Y, wherein each of the two fifth anchoring structures 45 is correspondingly disposed at the respective end of the first guide block 331 along the second direction Y; and a third in-plane guide elastic member 73 for connecting each fifth anchoring structure 45 to the corresponding end of the first guide block 331 along the second direction Y; each of the second guide blocks 332 comprises two ends disposed along the first direction X; the plurality of anchoring structures including two sixth anchoring structures 46 spaced apart along the first direction X and disposed at the two ends of each second guide block 332 along the first direction X, wherein each of the two sixth anchoring structures 46 is correspondingly disposed at the respective end of the second guide block 332 along the first direction X; and a fourth in-plane guide elastic member 74 for connecting each sixth anchoring structure 46 to the corresponding end of the second guide block 332 along the first direction X. The three-axis gyroscope further comprises ninth elastic members 69, each first guide block 331 has a first side surface 334 facing the other first guide block 331 along the first direction X, and the first side surface 334 is connected to the two second guide blocks 332 via the ninth elastic members 69; the three-axis gyroscope further comprises tenth elastic members 70, each second guide block 332 has a second side surface 335 facing the second direction Y away from the other second guide block 332, the tenth elastic members 70 for connecting the second side surface 335 of one second guide block 332 to the fifth mass block 31 and the second side surface 335 of the other second guide block 332 to the sixth mass block 32.

In the drive modality as shown in FIG. 9, the second guide blocks 332 are easily pulled by the fifth mass block 31 and the sixth mass block 32 to reversely move along the second direction Y, and the first guide blocks 331 are easily pulled by the second guide blocks 332 to reversely move along the first direction X, thereby preventing the fifth mass block 31 and the sixth mass block 32 from moving in the same direction. The force directions of the third guide portion 33 at certain time are as shown in FIG. 9 and FIG. 14.

In this embodiment, the first guide blocks 331 are connected to the fifth anchoring structures 45 along the second direction Y through third in-plane guide elastic members 73, so that the first guide blocks 331 can linearly move along the first direction X and be prevented from moving along the second direction Y. The second guide blocks 332 are connected to the sixth anchoring structures 46 along the first direction X through fourth in-plane guide elastic members 74, so that the second guide blocks 331 can linearly move along the second direction Y and be prevented from moving along the first direction.

In the drive modality as shown in FIG. 9, the two second guide blocks 332 move in the same direction with the fifth mass block 31 or the sixth mass block 32 connected to the second guide blocks, and pull the two first guide blocks 331 to be close to each other or far away from each other through the tenth elastic members 70, so that the fifth mass block 31 and the sixth mass block 32 can reversely do differential linear motion along the second direction Y under the drive of the drive structure 5, thus reducing the motion interference between the fifth mass block 31 and the sixth mass block 32, and avoiding the fifth mass block 31 and the sixth mass block 32 from moving in the same direction in the drive modality due to the mutual interference or the interference of the drive structure 5 to make the three-axis gyroscope in a parasitic modality. Furthermore, in the third detection modality as shown in FIG. 14, the third guide portion 33 can remain stationary, which reduces a coupling error of the third sensitive structure 3 in different modalities and can further reduce the motion interference between the fifth mass block 31 and the sixth mass block 32, so that it is more convenient for realizing differential detection and improving the detection accuracy of the three-axis gyroscope.

Therefore, the arrangement of the third guide portion 33 can prevent the fifth mass block 31 and the sixth mass block 32 from moving in the same direction along the second direction Y, increase a frequency difference between the drive modality and the parasitic modality, reduce linear impact, vibration interference and other interferences in the same direction output by the third sensitive structure 3, and effectively improve the quality factor of the three-axis gyroscope in the drive modality.

According to the specific embodiments in FIG. 9 and FIG. 14, the two second guide blocks 332 can be respectively provided with actuators 333 to drive the second guide blocks 332, which further prevents the fifth mass block 31 and the sixth mass block 32 from moving in the same direction. Of course, the actuators 333 may not be provided. This will not be limited here.

It should be noted that the three-axis gyroscope in the present invention can be provided with one or more of the first guide portion 13, the second guide portion 23 and/or the third guide portion 33, or may not be provided with any guide portion. This will not be limited here.

In one specific embodiment, as shown in FIG. 1 to FIG. 14, the third sensitive structure 3 further includes a first detection block 34 and a second detection block 35 which are symmetrically arranged along the first direction X. The first detection block 34 comprises two ends disposed along the second direction Y; t the first detection block 34 comprises two ends disposed along the second direction Y; the plurality of anchoring structures including two seventh anchoring structures 47 spaced apart along the second direction Y and disposed at the two ends of first detection block 34 along the second direction Y, wherein each of the two seventh anchoring structures 47 is correspondingly disposed at the respective end of the first detection block 34 along the second direction Y; and a fifth in-plane guide elastic member 75 for connecting each seventh anchoring structure 47 to the corresponding end of the first detection block 34 along the second direction Y; the first detection block 34 comprises two ends disposed along the first direction X; the three-axis gyroscope further comprises eleventh elastic members 701 for connecting the two ends of the first detection block 34 along the first direction X and the fifth mass block 31; the second detection block 35 comprises two ends disposed along the second direction Y; the plurality of anchoring structures including two eighth anchoring structures 48 spaced apart along the second direction Y and disposed at the two ends of second detection block 35 along the second direction Y, wherein each of the two eighth anchoring structures 48 is correspondingly disposed at the respective end of the second detection block 35 along the second direction Y; and a sixth in-plane guide elastic 76 member for connecting each eighth anchoring structure 48 to the corresponding end of the second detection block 35 along the second direction Y; the second detection block 35 comprises two ends disposed along the first direction X; the three-axis gyroscope further comprises twelfth elastic members 702 for connecting the two ends of the second detection block 35 along the first direction X and the sixth mass block 32;

In the drive modality as shown in FIG. 2 and FIG. 9, the first detection block 34 and the second detection block 35 remain stationary.

In the third detection modality as shown in FIG. 7 and FIG. 14, the first detection block 34 can move in the same direction with the fifth mass block 31. The second detection block 35 can move in the same direction with the sixth mass block 32.

In this embodiment, the first detection block 34 is connected to the seventh anchoring structures 47 along the second direction Y through fifth in-plane guide elastic members 75, and the second detection block 35 is connected to the eighth anchoring structures 48 along the second direction Y through sixth in-plane guide elastic members 76, so that the first detection block 34 and the second detection block 35 can linearly move along the first direction X, and be prevented from moving along the second direction Y.

Therefore, in the drive modality as shown in FIG. 2 and FIG. 9, the first detection block 34 and the second detection block 35 can remain stationary. In the third detection modality as shown in FIG. 7 and FIG. 14, the first detection block 34 can slide in the same direction with the fifth mass block 31 along the first direction X, and the second detection block 35 can slide in the same direction with the sixth mass block 32 along the first direction X, so that differential linear motion is formed between the first detection block 34 and the second detection block 35. The angular velocity along the third direction Z can be acquired by means of detecting the vibration displacements of the first detection block 34 and the second detection block 35 in the first direction X. The first detection block 34 and the second detection block 35 have vibration frequencies equal to the motion frequencies of the fifth mass block 31 and the sixth mass block 32, have smaller volumes, and are easier to measure. In addition, this structure can reduce the coupling errors of the first detection block 34 and the second detection block 35 in different modalities and improve the detection accuracy of the three-axis gyroscope.

The first detection block 34 and the second detection block 35 can be respectively arranged on outer sides of the fifth mass block 31 and the sixth mass block 32, or can be arranged on inner sides of the fifth mass block 31 and the sixth mass block 32 in the specific embodiments as shown in FIG. 7 to FIG. 14. This will not be limited here.

Specifically, according to the specific embodiments as shown in FIG. 7 to FIG. 14, when the first detection block 34 and the fifth detection block 35 are respectively arranged on the inner sides of the fifth mass block 31 and the sixth mass block 32, the fifth mass block 31 can be provided with a first sunken portion 311, and the sixth mass block 32 can be provided with a second sunken portion 321, so that the first detection block 34 is mounted to the first sunken portion 311 and is connected to the fifth mass block 31, and the second detection block 35 is mounted to the second sunken portion 321 and is connected to the sixth mass block 32.

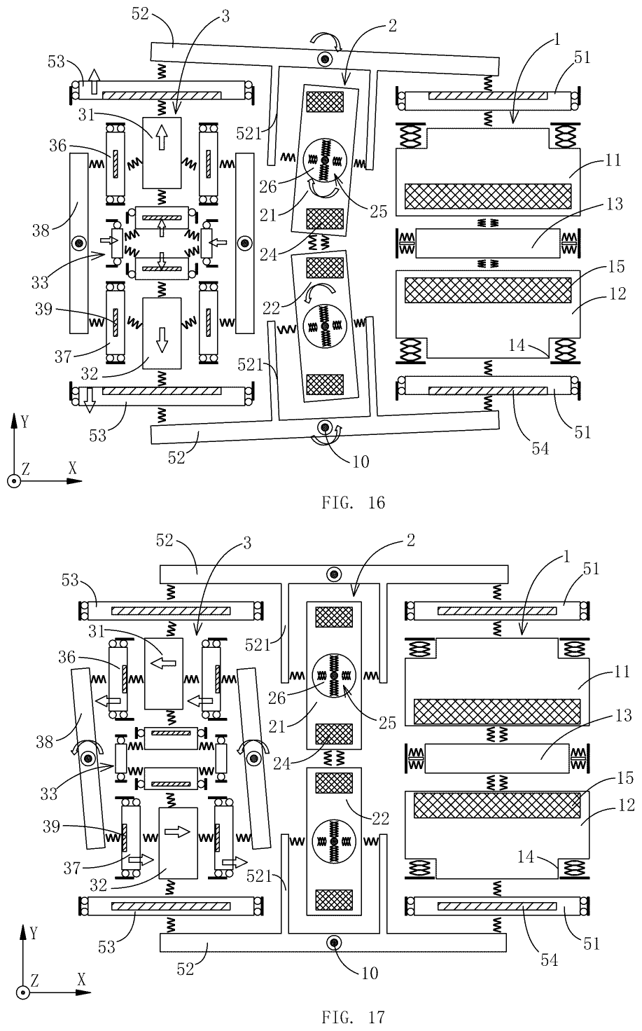

In another specific embodiment, as shown in FIG. 15 to FIG. 17, the third sensitive structure 3 further comprises two third detection blocks 36 symmetrically arranged along the second direction Y, two fourth detection blocks 37 symmetrically arranged along the second direction Y and two coupling levers 38 symmetrically arranged along the second direction Y, and the third detection blocks 36 and the fourth detection blocks 37 are symmetrically arranged about the first direction X. the three-axis gyroscope further comprises thirteenth elastic members 703, along the first direction X, one end of each of the two third detection blocks 36 is connected with the fifth mass block 31 through one of the thirteenth elastic members 703, and the other end is connected with one of the two coupling levers 38 through one of the thirteenth elastic members 703; one end of each of the two fourth detection blocks 37 is connected with the sixth mass block 32 through one of the thirteenth elastic members 703, and the other end is connected with one of the two coupling levers 38 through one of the thirteenth elastic members 703; along the second direction Y, each of the third detection blocks 36 comprises two ends disposed along the second direction Y; the plurality of anchoring structures including two ninth anchoring structures 49 spaced apart along the second direction Y and disposed at the two ends of third detection block 36 along the second direction Y, wherein each of the two ninth anchoring structures 49 is correspondingly disposed at the respective end of the third detection block 36 along the second direction Y; and a seventh in-plane guide elastic member 77 for connecting each ninth anchoring structure 49 to the corresponding end of the third detection block 36 along the second direction Y; each of the fourth detection blocks 37 comprises two ends disposed along the second direction Y; the plurality of anchoring structures including two tenth anchoring structures 50 spaced apart along the second direction Y and disposed at the two ends of fourth detection block 37 along the second direction Y, each of the two tenth anchoring structures 50 is correspondingly disposed at the respective end of the fourth detection block 37 along the second direction Y; and a eighth in-plane guide elastic member 78 for connecting each tenth anchoring structure 50 to the corresponding end of the fourth detection block 37 along the second direction Y.

In the drive modality as shown in FIG. 16, the third detection blocks 36 and the fourth detection blocks 37 remain stationary.

In the third detection modality as shown in FIG. 17, the two third detection blocks 36 can move in the same direction with the fifth mass block 31. The two fourth detection blocks 37 can move in the same direction with the sixth mass block 32. The coupling levers 38 can be pulled by the third detection blocks 36 and the fourth detection blocks 37 to rotate in the same direction around rotating shafts of the coupling levers.

In this embodiment, the two third detection blocks 36 are independent of each other, and the two fourth detection blocks 37 are independent of each other. The coupling levers 38 are simultaneously coupled with the mutually independent third detection blocks 36 and fourth detection blocks 37. The fifth mass block, the third detection blocks 36, the coupling levers 38, the fourth detection blocks 37, and the sixth mass block 37 are connected in sequence along a circumferential direction through the elastic members 6.

In the drive modality as shown in FIG. 16, the third detection blocks 36, the fourth detection blocks 37 and the coupling levers can remain stationary. In the third detection modality as shown in FIG. 17, the two third detection blocks 36, the two fourth detection blocks 37 and the two coupling levers 38 are pulled to move by the fifth mass block 31 and the sixth mass block 32, and the two third detection blocks 36, the two fourth detection blocks 37 and the two coupling levers 38 have the same motion frequencies as the fifth mass block 31 and the sixth mass block 32. Furthermore, the two coupling levers 38 have the same phase, and the third detection blocks 36 and the fourth detection blocks 37 have opposite phases, so that the degree of symmetry of a differential signal of the third sensitive structure 3 in the third detection modality can be effectively increased, the influence of common mode interference is reduced, and the detection accuracy of the three-axis gyroscope is further improved.

Centers of the two coupling levers 38 can be fixed by fixing members 10, so that the coupling levers 38 can rotate around their rotating shafts, which is convenient for realizing associated motion between all the components of the third sensitive structure 3 and improves the structural stability of the three-axis gyroscope.

In one specific embodiment, as shown in FIG. 1, FIG. 8 and FIG. 15, the first sensitive structure 1 further includes the elastic members 6. Two ends of the first sensitive structure 1 along the second direction Y are also provided with connection portions14. The connection portions 14 are fixed to anchoring structures through the elastic members 6.

In this embodiment, each elastic member 6 is a structure that can deform along the first direction X and can also rotate towards the third direction Z, which is convenient for realizing the differential linear motion of the first sensitive structure 1 along the second direction Y in the driving modality as shown in FIG. 2, FIG. 9 and FIG. 16, and is also convenient for realizing that in the first detection modality of the first sensitive structure 1 as shown in FIG. 3, FIG. 4, FIG. 10 and FIG. 11, the opposite sides of the first mass block 11 and the second mass block 12 can reversely flip towards the third direction Z, causing the differential rotation motion between the first mass block 11 and the second mass block 12, thus generating the vibration displacement in the third direction Z. Thus, it is convenient for realizing differential detection. Moreover, the structure is simple, and the structural complexity of the three-axis gyroscope can be reduced.

In one specific embodiment, as shown in FIG. 1, FIG. 8 and FIG. 15, the three-axis gyroscope further includes first transducers 15, second transducers 24, and third transducers 39.

As shown in FIG. 4 and FIG. 11, along the third direction Z, the first transducers 15 and the first sensitive structure 1 are spaced apart to form capacitance, a change in the distance between the first transducers and the first sensitive structure causes the capacitance to change, and the capacitance change for detecting the vibration displacement of the first sensitive structure 1 along the third direction Z, or preventing an orthogonal error of the first detection modality, or matching the frequencies of the drive modality and the first detection modality.

As shown in FIG. 6 and FIG. 13, along the third direction Z, the second transducers 24 and the second sensitive structure 2 are spaced apart to form capacitance, a change in the distance between the second transducers and the second sensitive structure causes the capacitance to change, and the capacitance change for detecting the vibration displacement of the second sensitive structure 2 along the third direction Z, or preventing an orthogonal error of the second detection modality, or matching the frequencies of the drive modality and the first detection modality.

As shown in FIG. 7, FIG. 14 and FIG. 17, in a plane perpendicular to the third direction Z, the third transducers 39 and the third sensitive structure 3 are located in the same plane, and the third transducers 39 and the third sensitive structure 3 are spaced apart to form capacitance, a change in the distance between the third transducers and the third sensitive structure causes the capacitance to change, and the capacitance change for detecting the vibration displacement of the third sensitive structure 3 along the first direction X, or preventing an orthogonal error of the third detection modality, or matching the frequencies of the drive modality and the third detection modality.

In this embodiment, along the third direction Z, the first transducers 15 are located above or below the first sensitive structure 1, with a space, and the second transducers 24 are located above or below the second sensitive structure 2, with a space, so that an arrangement area of the first transducers 15 and the second transducers 24 can be enlarged, which can effectively increase the electromechanical coupling coefficient detected by the three-axis gyroscope and is convenient for detecting the vibration displacements of the first sensitive structure 1 and the second sensitive structure 2 along the third direction Z, thus improving the detection accuracy of the three-axis gyroscope and further reducing a detection error. The third transducers 39 and the third sensitive structure are located on the same plane, which is convenient for detecting the vibration displacement of the third sensitive structure 3 along the first direction X, thus reducing a detection error and improving the detection accuracy of the three-axis gyroscope.

The transducers of the first sensitive structure 1, the second sensitive structure 2 and the third sensitive structure 3 of the three-axis gyroscope in the present invention are independent of each other, which is convenient for realizing electrical orthogonal suppression, reducing the orthogonal errors of the first sensitive structure 1, the second sensitive structure 2 and the third sensitive structure 3 in the detection modalities, and improving the detection accuracy of the three-axis gyroscope.

As shown in FIG. 4 and FIG. 11, the capacitance is formed between the first transducers 15 and the first sensitive structure 1. As shown in FIG. 6 and FIG. 13, the capacitance is formed between the second transducers 24 and the second sensitive structure 2. As shown in FIG. 7, FIG. 14 and FIG. 17, the capacitance is formed between the third transducers 39 and the third sensitive structure 3.

In this embodiment, in the first detection modality as shown in FIG. 4 and FIG. 11, the first sensitive structure 1 senses the angular velocity along the first direction X. The first mass block 11 and the second mass block 12 move along the third direction Z under the action of the Coriolis force. If the first transducers 15 arranged above or below the first mass block 11 and the second mass block 12 along the third direction Z sense that a distance between the first mass block 11 and the second mass block 12 changes, the capacitance of the first transducers 15 will change. The value of the angular velocity along the first direction X can be obtained by means of detecting a changing value of the capacitance.

In the second detection modality as shown in FIG. 6 and FIG. 13, the second sensitive structure 2 senses the angular velocity along the second direction Y. The third mass block 21 and the fourth mass block 22 move along the third direction Z under the action of the Coriolis force. If the second transducers 24 arranged above or below the third mass block 21 and the fourth mass block 22 along the third direction Z sense that a distance between the third mass block 21 and the fourth mass block 22 changes, the capacitance of the second transducers 24 will change. The value of the angular velocity along the second direction Y can be obtained by means of detecting a changing value of the capacitance.

In the third detection modality as shown in FIG. 7, FIG. 14 and FIG. 17, the third sensitive structure 3 senses the angular velocity along the third direction Z. The fifth mass block 31 and the sixth mass block 32 move along the first direction X under the action of the Coriolis force, so that the fifth mass block 31 drives the first detection block 34 or the third detection blocks 36 to move along the first direction X, and the sixth mass block 32 drives the second detection block 35 or the fourth detection blocks 37 to move along the first direction X. If the third transducers 39 sense that distances from the first detection block 34, the second detection block 35, the third detection blocks 36 or the fourth detection blocks 37 change, the capacitance of the third transducers 39 will change. The value of the angular velocity along the third direction Z can be obtained by means of detecting a changing value of the capacitance.

Therefore, the capacitance is convenient for realizing the capacitance modality matching for the first sensitive structure 1, the second sensitive structure 2 and the third sensitive structure 3, which further improves the detection accuracy and stability of the three-axis gyroscope.

In one specific embodiment, as shown in FIG. 1, FIG. 8 and FIG. 15, the drive structure 5 includes first drive portions 51, drive arms 52, and third drive portions 53, and second drive portions 521 are formed on the drive arms 52. The three-axis gyroscope comprises fourth elastic members 64,The first drive portions 51 and the third drive portions 53 are respectively connected to both ends of the drive arms 52 along the first direction X through the fourth elastic members 64, and are respectively located on both sides of the second drive portions 521 along the first direction X. Each of the first drive portions 51 comprises two ends disposed along the first direction X; the plurality of anchoring structures including two first anchoring structures 41 spaced apart along the first direction X and disposed at the two ends of each first drive portion 51 along the first direction X, wherein each of the two first anchoring structures 41 is correspondingly disposed at the respective end of the first drive portion 51 along the first direction X; and a first in-plane guide elastic member 71 for connecting each first anchoring structure 41 to the corresponding end of the first drive portion 51 along the first direction X; each third drive portion 53 comprises two ends disposed along the first direction X; the plurality of anchoring structures including two second anchoring structures 42 spaced apart along the first direction X and disposed at the two ends of each third drive portion 53 along the first direction X, wherein each of the two second anchoring structures 42 is correspondingly disposed at the respective end of the third drive portion 53 along the first direction X; and a second in-plane guide elastic member 72 for connecting each second anchoring structure 42 to the corresponding end of the third drive portion 53 along the first direction X; There are two drive structures spaced along the second direction Y, one drive structure positioned on a side of the second mass block 21 facing away from the third mass block 22, and the other drive structure positioned on a side of the third mass block 22 facing away from the second mass block 21; each drive structure consists of a drive arm 52 extending along the first direction X, having a first drive portion 51 connected at one end along the first direction X and a third drive portion 53 connected at the other end along the first direction X, and a second drive portion 521 extending from the middle of the drive arm 52 along the second direction Y toward the other drive structure, the drive structure being connected to the second sensitive structure 2 exclusively through the second drive portion 521.

In this embodiment, the first drive portions 51, the second drive portions 521 and the third drive portions 53 in the drive structure 5 are symmetric along the second direction Y, and the motions between the first drive portions 51, the second drive portions 521 and the third drive portions 53 are associated and have the same frequency. Furthermore, symmetric portions of the first drive portions 51, the second drive portions 521 and the third drive portions 53 along the second direction Y have opposite phases, which can effectively increase the degree of symmetry of the differential signals of the three-axis gyroscope in the drive modality as shown in FIG. 2, FIG. 9 and FIG. 16 and reduce the influence of common mode interferences. In another aspect, the drive structure 5 is simple in structure, and can be stationary in the first detection modality, the second detection modality or the third detection modality, so that it is convenient for realizing mutual coupling of the first sensitive structure 1, the second sensitive structure 2 and the third sensitive structure 3 in the first detection modality, the second detection modality or the third detection modality, avoiding a large coupling error, and improving the detection accuracy of the three-axis gyroscope.

In one specific embodiment, as shown in FIG. 1, FIG. 8 and FIG. 15, the drive structure 5 further includes drive electrodes 54. The drive electrodes 54 are mounted on the first drive portions 51 and the second drive portions 521. The drive electrodes 54 are spaced apart from the first drive portions 51 and/or the third drive portions 53 to form drive capacitance. The first drive portions 51 and the third drive portions 53 can move along the second direction Y, and drive the second drive portions 521 to rotate through the fourth elastic members 64 connected to the drive arms 52.

In this embodiment, when the three-axis gyroscope is turned on, the drive capacitance of the drive electrodes 54 changes, so that the first drive portions 51 and the second drive portions 521 can drive the first sensitive structure 1 and the third sensitive structure 3 to move in the second direction Y. At the same time, the first drive portions 51 and the second drive portions 521 can drive the third drive portions 53 to drive the second sensitive structure 2 to rotate, so that the three-axis gyroscope is in the drive modality shown in FIG. 2, FIG. 9 and FIG. 16. Therefore, this structure is convenient for controlling the motions of the first sensitive structure 1, the second sensitive structure 2 and the third sensitive structure 3, and can simplify the structure of the drive structure 5, thereby simplifying the structure of the three-axis gyroscope and saving the installation space for the three-axis gyroscope.

The drive arms 52 can be fixed by fixing members 10, so that the drive arms 52 can rotate around the fixing members 10, which is convenient for realizing associated motions between the first drive portions 51, the second drive portions 521 and the third drive portions 53, and improving the stability of the three-axis gyroscope.

In one specific embodiment, as shown in FIG. 1, FIG. 8 and FIG. 15, the second sensitive structure 2 also includes rotational guide elastic members 25. The third mass block 21 and the fourth mass block 22 are provided with first hole structures 26. The rotational guide elastic members 25 are located in the first hole structures 26.

In this embodiment, the axis of each rotational guide elastic member 25 is fixed. In the driving modality as shown in FIG. 2, FIG. 9 and FIG. 16, the rotational guide elastic members 25 can guide the third mass block 21 and the fourth mass block 22 to rotate in a plane perpendicular to the third direction Z around the axes of the rotational guide elastic members 25. In the second detection modality as shown in FIG. 6 and FIG. 13, two ends of the rotational guide elastic members 25 along the second direction Y can rotate in the plane perpendicular to the first direction X with the third mass block 21 or the fourth mass block 22. Therefore, the arrangement of the rotational guide elastic members 25 improves the steadiness of the rotations of the third mass block 21 and the fourth mass block 22, thereby improving the stability of the three-axis gyroscope.

The foregoing is merely illustrative of embodiments of the present invention, and it should be noted that modifications may be made to those skilled in the art without departing.

What is claimed is:

1. A three-axis gyroscope, comprising a drive structure for driving the three-axis gyroscope,
a first sensitive structure for sensing an angular velocity in a first direction; a second sensitive structure for sensing an angular velocity in a second direction; and a third sensitive structure for sensing an angular velocity in a third direction; wherein the three-axis gyroscope comprises first elastic members for connecting the first sensitive structure and the drive structure; the first sensitive structure comprises a first mass block and a second mass block, the first mass block and the second mass block are arranged along the second direction and are symmetrically arranged with respect to the first direction;
the three-axis gyroscope further comprises second elastic members for connecting the second sensitive structure and the drive structure; the second sensitive structure comprises a third mass block and a fourth mass block, the third mass block and the fourth mass block are arranged along the second direction and are symmetrically arranged with respect to the first direction;
the three-axis gyroscope further comprises third elastic members for connecting the third sensitive structure and the drive structure; the third sensitive structure comprises a fifth mass block and a sixth mass block, the fifth mass block and the sixth mass block are arranged along the second direction and are symmetrically arranged with respect to the first direction; and a plurality of anchoring structures for fixing the drive structure, the first sensitive structure, the second sensitive structure and the third sensitive structure;
wherein the first direction, the second direction and the third direction are orthogonal to each other; the three-axis gyroscope has a drive modality, a first detection modality, a second detection modality and a third detection modality;
the drive structure comprises first drive portions, drive arms, and third drive portions, and second drive portions are formed on the drive arms; the three-axis gyroscope comprises fourth elastic members, the first drive portions and the third drive portions are respectively connected to two end portions of the drive arms along the first direction through the fourth elastic members, and are respectively located on two sides of the second drive portions along the first direction;
the first drive portions are connected with the first sensitive structure through the first elastic members; the second drive portions are connected with the second sensitive structure through the second elastic members; and the third drive portions are connected with the third sensitive structure through the third elastic members;
each first drive portion comprises two ends disposed along the first direction; the plurality of anchoring structures including two first anchoring structures spaced apart along the first direction and disposed at the two ends of each first drive portion along the first direction, wherein each of the two first anchoring structures is correspondingly disposed at the respective end of the first drive portion along the first direction; and a first in-plane guide elastic member for connecting each first anchoring structure to the corresponding end of the first drive portion along the first direction; each third drive portion comprises two ends disposed along the first direction; the plurality of anchoring structures including two second anchoring structures spaced apart along the first direction and disposed at the two ends of each third drive portion along the first direction, wherein each of the two second anchoring structures is correspondingly disposed at the respective end of the third drive portion along the first direction; and a second in-plane guide elastic member for connecting each second anchoring structure to the corresponding end of the third drive portion along the first direction; the drive structure further comprises drive electrodes which are mounted on the first drive portions and the third drive portions; and the drive electrodes are spaced apart from the first drive portions and/or the third drive portions to form drive capacitance; the first drive portions and the third drive portions can move along the second direction, and drive the second drive portions to rotate through the fourth elastic members connected to the drive arms;
in the drive modality, the first drive portions can drive the first mass block and the second mass block to move along the second direction and the first mass block and the second mass block can move towards or away from each other in the second direction; each of the third mass block and the fourth mass block is provided with a rotating shaft having an extending direction parallel to the third direction; the second drive portions drive the third mass block and the fourth mass block to rotate reversely around respective rotating shafts, and the third mass block and the fourth mass block have facing sides along the second direction, and the facing sides are simultaneously rotate towards the third sensitive structure or the first sensitive structure; the third drive portions can drive the fifth mass block and the sixth mass block to move along the second direction and the fifth mass block and the sixth mass block can move towards or away from each other in the second direction;
wherein when the facing sides of the third mass block and the fourth mass block along the second direction rotate around the third direction toward the third sensitive structure, the fifth mass block and the sixth mass block move away from each other in the second direction, and the first mass block and the second mass block move towards each other in the second direction; motion directions of the first mass block and the fifth mass block are opposite;
in the first detection modality, the drive structure, the second sensitive structure and the third sensitive structure remain stationary, the first mass block comprises a first end facing the second mass block in the second direction; the second mass block comprises a second end facing the first mass block in the second direction; the first end and the second end can move away from each other in the third direction, generating a vibration displacement in the third direction, and an angular velocity along the first direction can be acquired by detecting the vibration displacements of the first mass block and the second mass block in the third direction;
in the second detection modality, the drive structure, the first sensitive structure and the third sensitive structure remain stationary, the third mass block and the fourth mass block rotate about the third direction in opposite directions to generate a vibration displacement in the third direction; and an angular velocity along the second direction can be acquired by detecting the vibration displacements of the third mass block and the fourth mass block in the third direction;
in the third detection modality, the drive structure, the first sensitive structure and the second sensitive structure remain stationary, and the fifth mass block and the sixth mass block can move away from or towards each other in the first direction to generate a vibration displacement in the first direction, and an angular velocity along the second direction can be acquired by detecting the displacement along the first direction.

2. The three-axis gyroscope according to claim 1, wherein the first sensitive structure further comprises a first guide portion; the first guide portion comprises two ends disposed along the first direction; the plurality of anchoring structures including two third anchoring structures spaced apart along the first direction and disposed at the two ends the first guide portion along the first direction, wherein each of the two third anchoring structures is correspondingly disposed at the respective end of the first guide portion along the first direction; and the three-axis gyroscope further comprises fifth elastic members for connecting each third anchoring structure to the corresponding end of the first guide portion along the first direction; the first guide portion further comprises two ends disposed along the second direction, the three-axis gyroscope further comprises sixth elastic members for connecting one end of the first guide portion along the second direction to the first mass block and the other end of the first guide portion along the second direction to the second mass block along the second direction;
in the drive modality, the first guide portion is pulled by the first mass block and the second mass block to remain stationary, so as to prevent the first mass block and the second mass block from moving in the same direction along the second direction; and
in the first detection modality, the first guide portion is pulled by the first mass block and the second mass block to rotate around the third direction with the third direction as the rotation axis.

3. The three-axis gyroscope according to claim 1, wherein the second sensitive structure further comprises a second guide portion; the second guide portion comprises two ends disposed along the first direction; the plurality of anchoring structures including two fourth anchoring structures spaced apart along the first direction and disposed at the two ends of the second guide portion along the first direction, wherein each of the two fourth anchoring structures is correspondingly disposed at the respective end of the second guide portion along the first direction; and the three-axis gyroscope further comprises seventh elastic members for connecting each fourth anchoring structure to the corresponding end of the second guide portion along the first direction; the second guide portion further comprises two ends disposed along the second direction, the three-axis gyroscope further comprises eighth elastic members for connecting one end of the second guide portion along the second direction to the third mass block and the other end of the second guide portion along the second direction to the fourth mass block along the second direction;
in the drive modality, the second guide portion is pulled by the third mass block and the fourth mass block to do reciprocating motion along the first direction, so as to prevent the third mass block and the fourth mass block from rotating in the same direction along the third direction; and
in the second detection modality, the second guide portion is pulled by the third mass block and the fourth mass block and capable of doing reciprocating motion along the third direction.

4. The three-axis gyroscope according to claim 1, wherein the third sensitive structure further comprises a third guide portion; the third guide portion comprises two first guide blocks extending along the second direction arranged symmetrically in the second direction, and two second guide blocks extending along the first direction arranged symmetrically in the first direction;
each of the first guide blocks comprises two ends disposed along the second direction; the plurality of anchoring structures including two fifth anchoring structures spaced apart along the second direction and disposed at the two ends of each first guide block along the second direction, wherein each of the two fifth anchoring structures is correspondingly disposed at the respective end of the first guide block along the second direction; and a third in-plane guide elastic member for connecting each fifth anchoring structure to the corresponding end of the first guide block along the second direction;
each of the second guide blocks comprises two ends disposed along the first direction; the plurality of anchoring structures including two sixth anchoring structures spaced apart along the first direction and disposed at the two ends of each second guide block along the first direction, wherein each of the two sixth anchoring structures is correspondingly disposed at the respective end of the second guide block along the first direction; and a fourth in-plane guide elastic member for connecting each sixth anchoring structure to the corresponding end of the second guide block along the first direction;
the three-axis gyroscope further comprises ninth elastic members, each first guide block has a first side surface facing the other first guide block along the first direction, and the first side surface is connected to the two second guide blocks via the ninth elastic members; the three-axis gyroscope further comprises tenth elastic members, each second guide block has a second side surface facing the second direction away from the other second guide block, the tenth elastic members for connecting the second side surface of one second guide block to the fifth mass block and the second side surface of the other second guide block to the sixth mass block;
in the drive modality, the second guide blocks are pulled by the fifth mass block and the sixth mass block to reversely move along the second direction, and the first guide blocks are pulled by the second guide blocks to reversely move along the first direction, thereby preventing the fifth mass block and the sixth mass block from moving in the same direction.

5. The three-axis gyroscope according to claim 1, wherein the third sensitive structure further comprises a first detection block and a second detection block which are symmetrically arranged along the first direction; the first detection block comprises two ends disposed along the second direction; the plurality of anchoring structures including two seventh anchoring structures spaced apart along the second direction and disposed at the two ends of first detection block along the second direction, wherein each of the two seventh anchoring structures is correspondingly disposed at the respective end of the first detection block along the second direction; and a fifth in-plane guide elastic member for connecting each seventh anchoring structure to the corresponding end of the first detection block along the second direction; the first detection block comprises two ends disposed along the first direction; the three-axis gyroscope further comprises eleventh elastic members for connecting the two ends of the first detection block along the first direction and the fifth mass block;
the second detection block comprises two ends disposed along the second direction; the plurality of anchoring structures including two eighth anchoring structures spaced apart along the second direction and disposed at the two ends of second detection block along the second direction, wherein each of the two eighth anchoring structures is correspondingly disposed at the respective end of the second detection block along the second direction; and a sixth in-plane guide elastic member for connecting each eighth anchoring structure to the corresponding end of the second detection block along the second direction; the second detection block comprises two ends disposed along the first direction; the three-axis gyroscope further comprises twelfth elastic members for connecting the two ends of the second detection block along the first direction and the sixth mass block;
in the drive modality, the first detection block and the second detection block remain stationary;
in the third detection modality, the first detection block and the fifth mass block have the same direction of motion; and the second detection block and the sixth mass block have the same direction of motion.

6. The three-axis gyroscope according to claim 4, wherein the third sensitive structure further comprises a first detection block and a second detection block which are symmetrically arranged along the first direction; the first detection block comprises two ends disposed along the second direction; the plurality of anchoring structures including two seventh anchoring structures spaced apart along the second direction and disposed at the two ends of first detection block along the second direction, wherein each of the two seventh anchoring structures is correspondingly disposed at the respective end of the first detection block along the second direction; and a fifth in-plane guide elastic member for connecting each seventh anchoring structure to the corresponding end of the first detection block along the second direction; the first detection block comprises two ends disposed along the first direction; the three-axis gyroscope further comprises eleventh elastic members for connecting the two ends of the first detection block along the first direction and the fifth mass block;
the second detection block comprises two ends disposed along the second direction; the plurality of anchoring structures including two eighth anchoring structures spaced apart along the second direction and disposed at the two ends of second detection block along the second direction, wherein each of the two eighth anchoring structures is correspondingly disposed at the respective end of the second detection block along the second direction; and a sixth in-plane guide elastic member for connecting each eighth anchoring structure to the corresponding end of the second detection block along the second direction; the second detection block comprises two ends disposed along the first direction; the three-axis gyroscope further comprises twelfth elastic members for connecting the two ends of the second detection block along the first direction and the sixth mass block;
in the drive modality, the first detection block and the second detection block remain stationary;
in the third detection modality, the first detection block and the fifth mass block have the same direction of motion; and the second detection block and the sixth mass block have the same direction of motion.

7. The three-axis gyroscope according to claim 4, wherein the third sensitive structure further comprises two third detection blocks symmetrically arranged along the second direction, two fourth detection blocks symmetrically arranged along the second direction and two coupling levers symmetrically arranged along the second direction, and both the third detection blocks and the fourth detection blocks extend along the second direction, the third detection blocks and the fourth detection blocks are symmetrically arranged about the first direction;
the three-axis gyroscope further comprises thirteenth elastic members, along the first direction, one end of each of the two third detection blocks is connected with the fifth mass block through one of the thirteenth elastic members, and the other end is connected with one of the two coupling levers through one of the thirteenth elastic members; one end of each of the two fourth detection blocks is connected with the sixth mass block through one of the thirteenth elastic members, and the other end is connected with one of the two coupling levers through one of the thirteenth elastic members;
along the second direction, each of the third detection blocks comprises two ends disposed along the second direction; the plurality of anchoring structures including two ninth anchoring structures spaced apart along the second direction and disposed at the two ends of third detection block along the second direction, wherein each of the two ninth anchoring structures is correspondingly disposed at the respective end of the third detection block along the second direction; and a seventh in-plane guide elastic member for connecting each ninth anchoring structure to the corresponding end of the third detection block along the second direction; each of the fourth detection blocks comprises two ends disposed along the second direction; the plurality of anchoring structures including two tenth anchoring structures spaced apart along the second direction and disposed at the two ends of fourth detection block along the second direction, wherein each of the two tenth anchoring structures is correspondingly disposed at the respective end of the fourth detection block along the second direction; and a eighth in-plane guide elastic member for connecting each tenth anchoring structure to the corresponding end of the fourth detection block along the second direction;
in the drive modality, the third detection blocks and the fourth detection blocks remain stationary;
in the third detection modality, the two third detection blocks move in the same direction with the fifth mass block; the two fourth detection blocks move in the same direction with the sixth mass block; and the coupling levers are pulled by the third detection blocks and the fourth detection blocks to rotate around the third direction, and the rotation direction of the coupling levers is the same.

8. The three-axis gyroscope according to claim 1, wherein the three-axis gyroscope further comprises first transducers, second transducers, and third transducers;
along the third direction, the first transducers and the first sensitive structure are spaced apart to form capacitance, a change in the distance between the first transducers and the first sensitive structure causes the capacitance to change, and the capacitance change for detecting the vibration displacement of the first sensitive structure along the third direction, or preventing an orthogonal error of the first detection modality, or matching the frequencies of the drive modality and the first detection modality;
along the third direction, the second transducers and the second sensitive structure are spaced apart to form capacitance, a change in the distance between the second transducers and the second sensitive structure causes the capacitance to change, and the capacitance change for detecting the vibration displacement of the second sensitive structure along the third direction, or preventing an orthogonal error of the second detection modality, or matching the frequencies of the drive modality and the second detection modality; and
the third transducers and the third sensitive structure are located in the same plane perpendicular to the third direction, and the third transducers and the third sensitive structure are spaced apart to form capacitance, a change in the distance between the third transducers and the third sensitive structure causes the capacitance to change, and the capacitance change for detecting the vibration displacement of the third sensitive structure along the first direction, or preventing an orthogonal error of the third detection modality, or matching the frequencies of the drive modality and the third detection modality.

9. The three-axis gyroscope according to claim 1, wherein the second sensitive structure further comprises rotational guide elastic members; the third mass block and the fourth mass block are provided with first hole structures; and the rotational guide elastic members are located in the first hole structures.

10. The three-axis gyroscope according to claim 5, wherein the fifth mass block is provided with a first sunken portion and the sixth mass block is provided with a second sunken portion; the first detection block is disposed within the first sunken portion of the fifth mass block and is connected to the fifth mass block; the second detection block is disposed within the second sunken portion of the sixth mass block and is connected to the sixth mass block.

11. The three-axis gyroscope according to claim 1, wherein two drive structures spaced along the second direction, one drive structure positioned on a side of the second mass block facing away from the third mass block, and the other drive structure positioned on a side of the third mass block facing away from the second mass block; each drive structure consists of a drive arm extending along the first direction, having a first drive portion connected at one end along the first direction and a third drive portion connected at the other end along the first direction, and a second drive portion extending from the middle of the drive arm along the second direction toward the other drive structure, the drive structure being connected to the second sensitive structure exclusively through the second drive portion.
